(19) United States
(12) Patent Application Publication
(10) Pub. No.: US 2008/0005634 A1
(43) Pub. Date: Jan. 3, 2008

(54) SCAN CHAIN CIRCUITRY THAT ENABLES SCAN TESTING AT FUNCTIONAL CLOCK SPEED

(76) Inventors: Gary D. Grise, Colchester, VT (US); Steven F. Oakland, Colchester, VT (US); Mark R. Taylor, Essex Junction, VT (US)

Correspondence Address: DOWNS RACHLIN MARTIN PLLC, 199 MAIN ST, PO BO 190, BURLINGTON, VT, 05402-0190, US

(21) Appl. No.: 11/427,659

(22) Filed: Jun. 29, 2006

(51) Int. Cl. G01R 31/28

(52) U.S. Cl. 714/726

(57) ABSTRACT

Boundary scan circuitry that includes a plurality of scan cells that each contain two scan registers each for storing a respective test value. During on-chip or inter-chip testing, one of the scan registers is responsive to a functional clock signal so that the test cell generates transition delay test data having at least one state transition made at the speed of the functional clock signal. The transition delay test data allows the integrity of on-chip functional circuitry or the integrity of inter-chip circuitry to be verified at full functional speed.

### FIELD OF THE INVENTION

The present invention generally relates to the field of integrated circuits. In particular, the present invention is directed to scan chain circuitry that enables scan testing at functional clock speed.

### BACKGROUND OF THE INVENTION

Conventional integrated circuit (IC) scan testing has two primary functions. First, in a multi-chip context, scan testing allows the integrity of inter-chip connections to be verified. This type of scan testing is commonly referred to as “boundary scan” testing and is the subject of the Institute of Electrical and Electronics Engineer (IEEE) standard 1149.1, which is incorporated herein by reference in its entirety as background and contextual information. Second, in a single chip context, scan testing allows functional blocks of integrated circuitry to be isolated from the external pins as described in the 1149.1 standard or, in the case of the IEEE 1500 standard being developed wherein a boundary scan is surrounding circuit cores internal to the chip, to isolate the cores from external logic and then these structures are tested at test clock speeds that are typically several orders of magnitude slower than the functional speed of that block. Generally, there are two types of functional block scan testing known as “full scan” and “partial scan” testing. Functional blocks are generally tested at full functional speed using built-in self test (BIST) circuitry or external automated testing equipment (ATE), or a combination of both. Any circuitry provided for scan testing is typically not utilized, at least for its scanning ability, during full functional speed testing.

FIG. 1 illustrates an IC chip 10 (here, the device under test (DUT)), having core logic 14 (a functional block) and a boundary scan circuitry arrangement 18 pursuant to the INTEST instruction of the IEEE 1149.1 standard. In accordance with the IEEE 1149.1 standard, boundary scan circuitry arrangement 18 includes a test access port (TAP) 22 and a scan chain 26 comprising a plurality of input scan cells 30 and a plurality of output scan cells 34. TAP 22 includes two input ports, a test data input port 38 and a TAP control input port 42, and one output, a test data output port 46. During testing, input scan cells 30 act as a serial-in, parallel-out shift register, i.e., test values are serially cascaded into the input scan cells and then output from the input scan cells into core logic 14 in parallel with each other for the test of the core logic. Conversely, output scan cells 34 act as a parallel-in, serial out shift register, i.e., the resultant values from the test of core logic 14 (the values output by the core logic based on the input test values) are received in parallel from the core logic and then cascaded out of the output scan cells in serial fashion. Test data input port 38 allows the input test values to be scanned into the individual input test cells 30, and test data output port 46 allows resultant test values to be scanned out of IC chip 10. The scanning of input and output values to and from scan chain 26 is controlled via TAP control input port 42.

FIG. 2 illustrates a conventional scan cell 50 pursuant to IEEE 1149.1 that is typically used for each of input scan cells 30 of FIG. 1. Referring to FIG. 2, a basic version of scan cell 50 consists of a scan register (e.g., flip-flop or latch) 54 and a pair of multiplexers (MUXs) 58, 62. MUX 58 has as its input a “Signal In” input 64 and a “Scan In” input 68 and is responsive to a “Shift/Load” selector signal 72. MUX 62 has as its input Signal In input 64 and a “Latched” input 76 that receives the latched value of scan register 54. MUX 62 is responsive to a “Mode” selector signal 80. Depending upon the location of scan cell 50 in scan chain 26 (FIG. 1), Scan In input 68 is connected to either TAP 22 (FIG. 1) or another input scan cell 30 (FIG. 1).

Testing consists of a scan operation to load in a stimulus and a capture operation to store the results of the test. Also during testing, Mode selector signal 80 is at a value that selects Latched input 76 so as to output to core logic 14 (FIG. 1) the test value latched in flip-flop 54. For the scan operation, Shift/Load signal 72 is used in the shift mode to select Scan In input 68 of multiplexer 58. Starting with the first boundary scan cell 30 (FIG. 1) in scan chain 26, the test values are then serially scanned-in from TAP 22 in a boundary scan mode. For boundary scan cells 30 that are not first in scan chain 26, the input to these cells are from the output (i.e., “Scan Out” output 84) of the preceding like boundary scan cell, as discussed below. During scanning, flip-flop 54 and the scanning of values into multiplexer 58 are typically clocked by a relatively low speed (compared to the normal operating functional speed of core logic 14 (FIG. 1)) Test Clock A signal 86.

In an alternative design of conventional scan cell 50, a second flip-flop (latch) 88 is located downstream of flip-flop 54 but off of the scan chain path 92. When provided, second flip-flop 88 is clocked by a second low speed (again, relative to the normal operating functional speed of core logic 14 (FIG. 1)) Test Clock B signal 94 and ensures that a test value being driven out of scan cell 50 (FIG. 2) via latched input 76 to MUX 62 is held while a new test value is being cascaded into the scan cell using Test Clock A signal 86 and Scan In input 68. A shortcoming of conventional boundary scan circuitry is that it does not provide a convenient way to transition delay test the functional circuitry (e.g., core logic) at the normal operating functional speed of the functional circuitry using the scanning ability of the scanning circuitry arrangement, such as scanning circuitry arrangement 18 of FIG. 1.

### SUMMARY OF THE INVENTION

In one aspect, the present invention is directed to a scan chain that enables functional speed testing of circuitry using a test clock signal and a functional clock signal. The scan chain comprises at least one scan cell in electrical communication with the circuitry. The at least one scan cell includes a first scan register responsive to the test clock signal and configured to latch a first scan test value as a function of the test clock signal. A second scan register is in series with the first scan register. The second scan register is responsive to the test clock signal and the functional clock signal and is configured to (i) latch a second scan test value as a function of the test clock signal and (ii) to flip-flop the second scan test value in response to the functional clock signal.

In another aspect, the present invention is directed to a method of at-speed testing circuitry having a functional speed. The method comprises cascading a test set of test values into a scan chain comprising a plurality of scan cells at a speed lower than the functional speed. The test set is selected for performing a transition delay test of the circuitry. After said scan chain has been loaded with said test set, each of said plurality of scan cells is caused to drive a transition delay test data signal into the circuitry at the functional speed. The transition delay test data signal contains a flip-flop function of a corresponding one of said test values.

### BRIEF DESCRIPTION OF THE DRAWINGS

For the purpose of illustrating the invention, the drawings show a form of the invention that is presently preferred. However, it should be understood that the present invention is not limited to the precise arrangements and instrumentalities shown in the drawings, wherein:

FIG. 1 is a high-level schematic diagram of an integrated circuit (IC) chip that includes boundary scan circuitry;

FIG. 2 is a schematic diagram of a prior art scan cell suitable for use with the boundary scan circuitry of FIG. 1;

FIG. 3 is a schematic diagram of a scan cell of the present invention that is suitable for use with the boundary scan circuitry of FIG. 1; and

FIG. 4 is a schematic diagram of an alternative scan cell of the present invention that is suitable for use with the boundary scan circuitry of FIG. 1.

### DETAILED DESCRIPTION

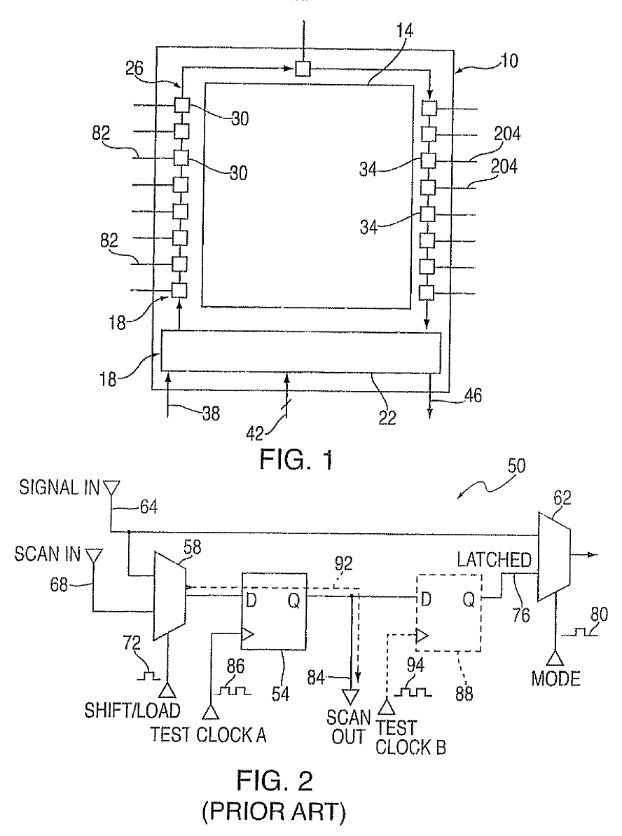

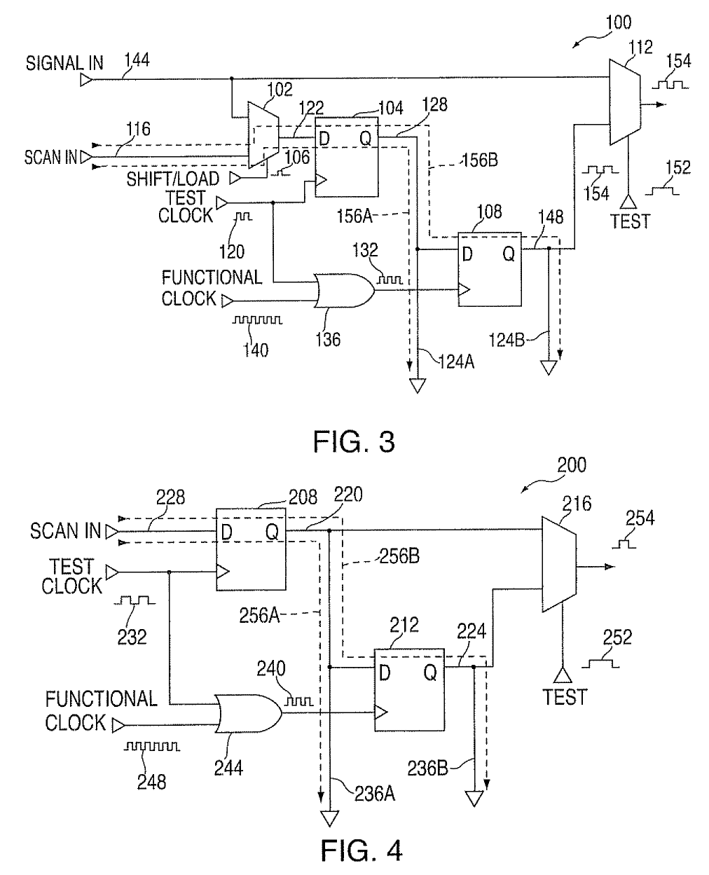

FIG. 3 shows a scan cell 100 of the present invention that may be used in scan circuitry, such as boundary scan circuitry arrangement 18 of FIG. 1. Scan cell 100 of FIG. 3 is unique in that it allows functional circuitry, e.g., core logic 14 of FIG. 1, located on the same integrated circuit (IC) chip, e.g., IC chip 10, as the scan cell to be transition delay tested at the normal operating functional speed of that circuitry. That is, scan cell 100 is configured to provide transition delay test data comprising one or more “flip-flop” transitions (e.g., 1→0, 0→1, 1→0→1, 0→1→0, etc.) to the functional circuitry at the speed that the circuitry was designed to function at under normal operating conditions, i.e., “functional speed,” so as to test the at-speed integrity of the circuitry. This functional speed is often much faster than a typical scan speed of 50 MHz to 125 MHz and can be in the Gigahertz range.

Scan cell 100 may include a first multiplexer (MUX) 102, a first scan register (e.g., flip-flop or latch) 104, a second scan register (e.g., flip-flop or latch) 108 and a second MUX 112. First multiplexer 102 may have as its selectable inputs a Scan In input 116 and a “Signal In” input 144 and is responsive to a “Shift/Load” selector signal 106. Depending on the location of scan cell 100 within a scan chain, Scan In input 116 may be connected to a test access port (TAP) (not shown, but like TAP 22 of FIG. 1) or the scan chain path output (e.g., either scan chain path output 124A or 124B) of another like scan cell. First scan register 104 is responsive to the output 122 of multiplexer 102 and a “Test Clock” signal 120. Test Clock signal 120 may be generated by suitable test clock circuitry (not shown) that oscillates at a speed lower than the functional speed. For example, if the functional speed of the functional circuitry at issue is on the order of 1 GHz, the speed of Test Clock signal 120 may be on the order of tens of MHz. Of course, as those skilled in the art will readily appreciate, these speeds are simply illustrative and by no means limiting.

Second scan register 108 may be respectively responsive to the output 128 of first scan register 104 and a clock signal 132 output from an OR-gate 136 having Test Clock signal 120 as one of its inputs and a Functional Clock signal 140 as the other of its inputs. Functional Clock signal 140 may be generated by suitable functional clock circuitry (not shown) that oscillates at the functional speed of the functional block at issue. The speed of the functional clock circuitry will typically be on the order of 1 GHz or more. MUX 112 may have as its inputs a Signal In input 144 connected to a signal contact or pin (not shown) and the output 148 of second scan register 108 and may be responsive to a Test signal 152. For example, when Test signal 152 is low, thereby indicating a normal, or non-test mode, MUX 112 would output the signal on Signal In input 144. Correspondingly, when Test signal 152 is high, thereby indicating the test mode, MUX 112 would output output 148 of second scan register 108. When second scan register 108 is clocked by Functional Clock signal 140 and Test signal 152 is high, indicating the test mode, a test data signal 154 having a transition will be output by the second scan register, if during a scan, a different value was loaded into first scan register 104 than was loaded into the second scan register (108) and MUX 112. Due to the at least one flip-flop transition caused by a transition of Functional Clock signal 140, test data signal 154 may be considered a functional speed transition delay test signal.

Depending upon how multiple ones of scan cell 100 are chained together to form a scan chain, e.g., scan chain 26 of FIG. 1, there are generally two scan chain paths 156A-B for cascading test values into the scan chain. If scan chain path output 124A of scan cell 100 is connected to the Scan In input (116) of a downstream like scan cell, the cascading of test values will proceed along scan chain path 156A that essentially cascades test values through only first scan register 104 and bypassing second scan register 108. Alternatively, if scan chain path output 124B is connected to the Scan In input (116) of a downstream like scan cell, the cascading of test values will proceed along scan chain path 156B that cascades test values through both first and second scan registers 104, 108. As those skilled in the art will appreciate, scan chain path 156B has greater flexibility in loading first and second scan registers 104, 108 with the desired test values. During cascading of test values into the scan chain, the functional clock is disabled so that clock signal 132 input into second scan register 108 is the slow speed Test Clock signal 120 that is also input into first scan register 104.

Although not shown, it is noted that scan cell 100 need not include first MUX 102 upstream of the first scan register 104. When provided, MUX 102 allows for loading of scan cell 100 via an external pin (not shown) through Signal In input 144 or via the scan chain through Scan In input 116. Those skilled in the art will readily understand how to modify scan cell 100 of FIG. 3 to exclude MUX 102.

FIG. 4 illustrates another scan cell 200 of the present invention. Scan cell 200 is generally suited for providing test data at functional speed to another chip (not shown) via the output pins of an IC chip, e.g., output pins 204 (FIG. 1) of IC chip 10. This allows scan cell 200 to be used to verify the integrity of the inter-chip circuitry, e.g., connections, at full functional speed using scanning techniques. Like scan cell 100 of FIG. 3, scan cell 200 of FIG. 4 includes first and second scan registers (flip-flops or latches) 208, 212 and a MUX 216. However, instead of MUX 216 having a Signal In input corresponding to Signal In input 144 of FIG. 3, one of the inputs to MUX 216 of FIG. 4 is the output 220 of first scan register 208 and the other of the inputs is the output 224 of second scan register 212. Other aspects of scan cell 200 may be identical to scan cell 100 of FIG. 3. That is, first scan register 208 may be responsive to a Scan In input 228 and a Test Clock signal 232. Depending on the location of scan cell 200 within a scan chain, Scan In input 228 may be connected to a test access port (TAP) (not shown, but like TAP 22 of FIG. 1) or the scan chain path output (e.g., either scan chain path output 236A or 236B) of another like scan cell. Test Clock signal 232 may be generated by suitable test clock circuitry (not shown) that oscillates at a speed lower than the functional speed. For example, if the functional speed of the functional circuitry at issue is on the order of 1 GHz, the speed of Test Clock signal 232 may be on the order of tens of MHz. Of course, as those skilled in the art will readily appreciate, these speeds are simply illustrative and by no means limiting.

Second scan register 212 may be responsive to the output 220 of first scan register 208 and a clock signal 240 output from an OR-gate 244 having Test Clock signal 232 as one of its inputs and a Functional Clock signal 248 as the other of its inputs. Functional Clock signal 248 may be generated by suitable functional clock circuitry (not shown) that oscillates at the functional speed of the functional block at issue. The speed of the functional clock circuitry will typically be on the order of 1 GHz or more. MUX 216 may be responsive to a Test signal 252. For example, when Test signal 252 is low, thereby indicating a normal, or non-test mode, MUX 216 would output the signal present on output 220 of first scan register 208. Correspondingly, when Test signal 252 is high, thereby indicating the test mode, MUX 216 would output the signal present on output 224 of second scan register 212. When second scan register 212 is clocked by Functional Clock signal 248 and Test signal 252 is high, indicating the test mode, a test data signal 254 having a transition will be output by the second scan register, if during scan, a different value was loaded into first scan register 208 than was loaded into second scan register 212 and MUX 216. Due to the at least one flip-flop transition, test data signal 254 may be considered a functional speed transition delay test signal.

Depending upon how multiple ones of scan cell 200 are chained together to form a scan chain, e.g., scan chain 26 of FIG. 1, there are generally two scan chain paths 256A-B for cascading test values into the scan chain. If scan chain path output 236A of scan cell 200 is connected to the Scan In input (228) of a downstream like scan cell, the cascading of test values will proceed along scan chain path 256A that essentially cascades test values through only first scan register 208 and bypassing second scan register 212. Alternatively, if scan chain path output 236B is connected to the Scan In input (228) of a downstream like scan cell, the cascading of test values will proceed along scan chain path 256B that cascades test values through both first and second scan registers 208, 212. As those skilled in the art will appreciate, scan chain path 256B has greater flexibility in loading first and second scan registers 208, 212 with the desired test values. During cascading of test values into the scan chain, the functional clock is disabled so that clock signal 240 input into second scan register 212 is the slow speed Test Clock signal 232 that is also input into first scan register 208.

Although the invention has been described and illustrated with respect to exemplary embodiments thereof, it should be understood by those skilled in the art that the foregoing and various other changes, omissions and additions may be made therein and thereto, without parting from the spirit and scope of the present invention.

What is claimed is:

1. A scan chain that enables functional speed testing of circuitry using a test clock signal and a functional clock signal, comprising:
at least one scan cell in electrical communication with the circuitry, said at least one scan cell including:
(a) a first scan register responsive to the test clock signal and configured to latch a first scan test value as a function of the test clock signal; and
(b) a second scan register in series with said first scan register, said second scan register responsive to the test clock signal and the functional clock signal and configured to (i) latch a second scan test value as a function of the test clock signal and (ii) to flip-flop said second scan test value in response to the functional clock signal.

2. A scan chain according to claim 1, wherein said first scan register has a first output and said second scan register has a second output and said at least one scan cell further comprises a multiplexer operatively configured to select between said first output and said second output, said multiplexer having a third output electrically connected to the circuitry.

3. A scan chain according to claim 2, wherein said at least one scan cell has a scan chain path that extends through said first scan register and bypasses said second scan register.

4. A scan chain according to claim 2, wherein said at least one scan cell has a scan chain path that extends through each of said first scan register and said second scan register.

5. A scan chain according to claim 1, wherein said at least one scan cell has an input that bypasses said first scan register and said second scan register and said second scan register has a first output, said at least one scan cell further comprising a multiplexer operatively configured to select between said input and said first output, said multiplexer having a second output electrically connected to the circuitry.

6. A scan chain according to claim 1, wherein the circuitry is functional circuitry and said at least one scan cell outputs a transition delay test signal to the circuitry.

7. A scan chain according to claim 1, wherein the circuitry is inter-chip connection circuitry and said at least one scan cell outputs a transition delay test signal to the circuitry.

8. A scan chain according to claim 1, wherein said at least one scan cell has a scan chain path that extends through said first scan register and bypasses said second scan register.

9. A scan chain according to claim 1, wherein said at least one scan cell has a scan chain path that extends through each of said first scan register and said second scan register.

10. A scan chain according to claim 1, further comprising a plurality of additional scan cells each substantially the same as said at least one scan cell, said plurality of scan cells and said at least one scan cell forming at least a portion of a boundary scan chain.

11. An integrated circuit chip, comprising:
a scan chain comprising a plurality of scan cells chained with one another in a cascade arrangement, each of said plurality of scan cells responsive to a test clock signal and a functional clock signal and including:
(i) a first scan register responsive to a test clock signal and configured to latch a first boundary scan value as a function of the test clock signal; and
(ii) a second scan register in series with said first scan register, said second scan register responsive to the test clock signal and the functional clock signal and configured to (i) latch a second scan value as a function of the test clock signal and (ii) flip-flop said second scan value in response to the functional clock signal.

12. An integrated circuit chip according to claim 11, wherein said first scan register has a first output and said second output has a second output and said at least one scan cell further comprises a multiplexer operatively configured to select between said first output and a second output.

13. An integrated circuit chip according to claim 11, wherein said at least one scan cell has an input that bypasses said first scan register and said second scan register and said second scan register has an output, said at least one scan cell further comprising a multiplexer operatively configured to select between said input and said output.

14. An integrated circuit chip according to claim 11, wherein said at least one scan cell has a scan chain path that extends through said first scan register and bypasses said second scan register.

15. An integrated circuit chip according to claim 11, wherein said at least one scan cell has a scan chain path that extends through each of said first scan register and said second scan register.

16. A method of implementing at-speed testing circuitry having a functional speed, comprising:
(a) cascading a test set of test values into a scan chain comprising a plurality of scan cells at a speed lower than the functional speed, said test set selected for performing a transition delay test of the circuitry; and
(b) after said scan chain has been loaded with said test set, causing each of said plurality of scan cells to drive a transition delay test data signal into the circuitry at the functional speed, said transition delay test data signal containing a flip-flop function of a corresponding one of said test values.

17. A method according to claim 16, wherein each of said plurality of scan cells includes a first scan register and a second scan register each containing corresponding ones of said test values, step (b) including clocking said second scan register with a functional clock.

18. A method according to claim 16, wherein each of said plurality of scan cells includes a first scan register and a second scan register, step (a) including cascading said test set into said scan chain so as to cascade past said second scan register so as to bypass said second scan register.

19. A method according to claim 16, wherein each of said plurality of scan cells includes a first scan register and a second scan register, step (a) including cascading said test set into said scan chain so as to cascade through said second scan register.

20. A method according to claim 16, wherein each of said plurality of scan cells includes a first scan register having first output and a second scan register having a second output, step (b) including selecting between said first and second outputs.
